(19) United States
(12) Patent Application Publication
(10) Pub. No.: US 2008/0291646 A1
(43) Pub. Date: Nov. 27, 2008

(54) ELECTRONIC CONTROL UNIT WITH A CENTRAL ELASTIC ELEMENT

(76) Inventors: Endrio FINO, Romano Canavese (IT); Fulvio CICOGNATI, Chieri (IT)

Correspondence Address: OSTROLENK FABER GERB & SOFFEN, 1180 AVENUE OF THE AMERICAS, NEW YORK, NY, 100368403, US

(21) Appl. No.: 12/122,842

(22) Filed: May 19, 2008

(30) Foreign Application Priority Data
May 21, 2007 (EP) 07425298.2

(51) Int. Cl. H05K 5/00

(52) U.S. Cl. 361/752

(57) ABSTRACT

An electronic control unit presenting: a printed circuit board, which supports an electric circuit, a plurality of electric/electronic components electrically connected to the electric circuit, and at least one connector electrically connected to the electrical circuit; a housing, which accommodates therein the printed circuit board and comprises a base which inferiorly supports the printed circuit board and a lid which superiorly closes the base; and at least one pressing element, which is formed by elastically deformable material, is arranged in central position and is compressed between the lid and the printed circuit board for pressing with interference against the printed circuit board.

The present invention relates to an electronic control unit.

The present invention finds advantageous application in an electronic control unit of an internal combustion engine, to which explicit reference will be made in the following description without because of this loosing in generality.

### BACKGROUND OF THE INVENTION

An electronic control unit for an internal combustion engine comprises a PCB (Printed Circuit Board), which supports an electronic circuit, a plurality of electric/electronic components electrically connected to the electric circuit, and at least one connector electrically connected to the electric circuit for connecting the electronic control unit to the internal combustion engine wiring. The printed circuit board is accommodated in a housing, which comprises a base which inferiorly supports the printed circuit board and a lid which superiorly closes the base.

Generally, in addition to its natural containing and mechanical protection function, base of housing performs the function of heat sink for dissipating the heat which is produced by electric/electronic components. For this reason, some constructive solutions contemplate that the printed circuit board is maintained pressed against the base of the housing by means of at least one central fastening screw which is arranged through a through hole obtained through the printed circuit board and is screwed into a blank threaded hole obtained through the base of the housing.

However, the presence of the fastening screw increases the assembly costs due to the need to manage the additional component constituted by fastening screw, perforating the printed circuit board, perforating and threading the housing base and screwing the fastening screw. Furthermore, the need to make a blank threaded hole for the fastening screw in the base of the housing obliges to make the base of the housing with an at least locally high thickness.

### SUMMARY OF THE INVENTION

It is the object of the present invention to make an electronic control unit which is free from the above-described drawbacks and is specifically easy and cost-effective to manufacture.

According to the present invention, an electronic control unit is made as claimed in the attached Claims.

### BRIEF DESCRIPTION OF THE DRAWINGS

The present invention will now be described with reference to the accompanying drawings which illustrate a non-limitative example of embodiment thereof, in which:

FIG. 1 is a perspective, exploded, diagrammatic view with parts removed for clarity of an electronic control unit for an internal combustion engine made according to the present invention;

FIG. 2 is a further perspective, exploded, diagrammatic view with parts removed for clarity of the electronic control unit in FIG. 1;

FIG. 3 is a side section view of the electronic control unit in FIG. 1;

FIG. 4 is a bottom view of the electronic control unit in FIG. 1; and

FIGS. 5 and 6 are two side section views of a fastening fin of the electronic control unit in FIG. 1 in an assembly configuration and in a fastening configuration, respectively.

### DETAILED DESCRIPTION OF THE INVENTION

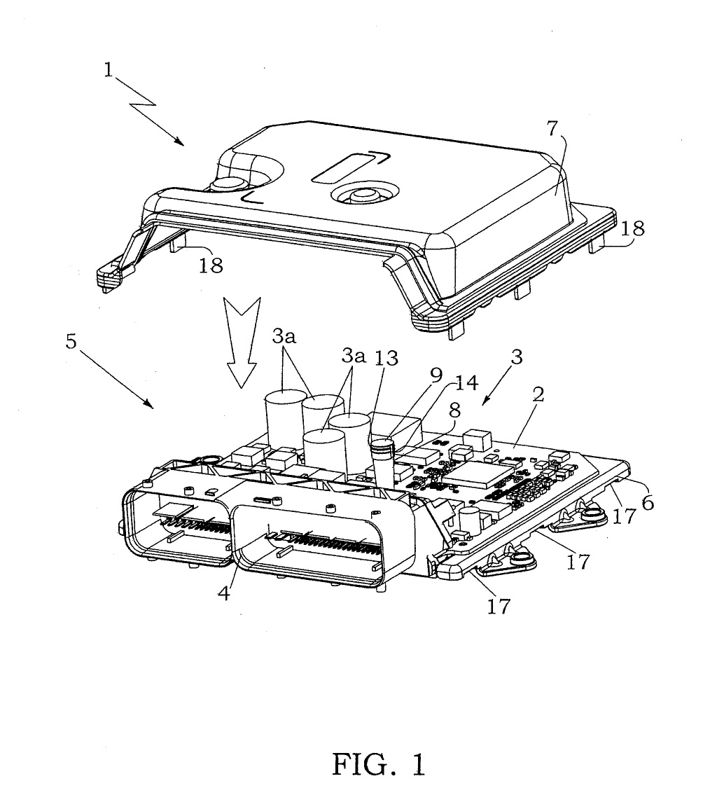

In FIG. 1, numeral 1 indicates as a whole an electronic control unit for an internal combustion engine.

Electronic control unit 1 comprises a printed circuit board 2, which supports an electric circuit, a plurality of electric/electronic components 3 electrically connected to the electric circuit, and a connector 4 electrically connected to the electric circuit to connect electronic control unit 1 to the internal combustion engine wiring. Specifically, printed circuit board 2 supports four electrolytic capacitors 3a, which have a cylindrical shape and present large dimensions and a heavy mass.

Furthermore, electronic control unit 1 comprises a housing 5, which presents a rectangular shape in plan, accommodates therein printed circuit board 2 and comprises a base 6 which inferiorly supports printed circuit board 2 and a lid 7 which superiorly closes base 6. In addition to its natural containing and mechanical protection function, base 6 of housing 5 performs the function of heat sink for dissipating the heat which is produced by electric/electronic components 3. Consequently, printed circuit board 2 is arranged in contact with base 6 of housing 5 and a paste which is thermally conducting and electrically insulating may be interposed between the lower surface of printed circuit board 2 and the upper surface of base 6 of housing 5 in order to increase the heat exchange.

According to a preferred embodiment, base 6 and lid 7 of housing 5 are formed by aluminium sheet using pressing technology by cold rolling of aluminium castings; in the embodiment shown in the accompanying figures, base 6 has a thickness of 2.5 mm and lid 7 has a thickness of 1.5 mm.

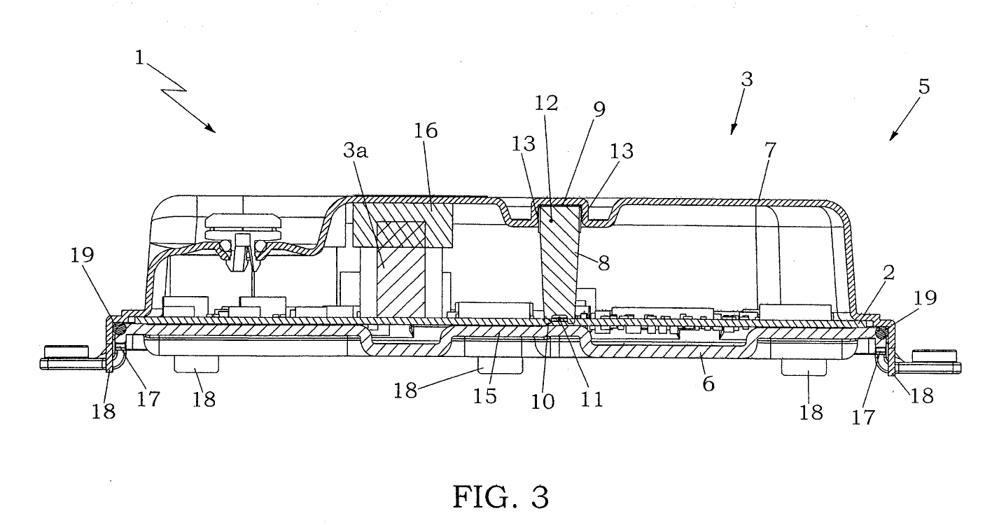

As shown in FIG. 3, in order to increase the heat exchange between printed board circuit 2 and base 6 of housing 5, it is necessary to keep printed circuit board 2 pressed against base 6 of housing 5 with a certain force. For this purpose, electronic control unit 1 comprises at least one pressing element 8, which is formed by elastically deformable material, is arranged in central position and is compressed between lid 7 and printed circuit board 2 for pressing with interference against printed circuit board 2.

Pressing element 8 presents a frustum-shape having a larger base 9 resting on lid 7 and a smaller base 10 resting on printed circuit board 2. According to a possible embodiment shown in the accompanying figures, smaller base 10 of pressing element 8 rests against printed circuit board 2 is rounded and presents a central blank hole 11. The function of central blank hole 11 is to confer a “suction cap” effect to smaller base 10 resting on printed circuit board 2 for increasing the transversal withholding force.

According to a preferred embodiment shown in the accompanying figures, lid 7 comprises an annular seat 12 which is cup-shaped and accommodates larger base 9 of pressing element 8 resting on lid 7. In order to increase the withholding force of pressing element 8 within seat 12, pressing element 8 presents two annular bulges 13 which are dimensioned by interference within seat 12. Moreover, in order to further increase the withholding force of pressing element 8 within seat 12, larger base 9 of pressing element 8 is fixed to lid 7 by gluing; i.e. a drop of glue (resin) is inserted inside seat 12 before driving larger base 9 of pressing element 8 inside seat 12. Preferably, pressing element 8 presents two axial side channels 14 to relieve the glue in excess at base 9; i.e. the glue in excess present inside seat 12 may leak from seat 12 during the driving of larger base 9 of pressing element 8 through two side channels 14.

According to a preferred embodiment, pressing element 8 is formed by silicone having for example a hardness of 80±5 shoreA. In the embodiment shown in the accompanying figures, pressing element 8 has a total height of 27 mm, larger base 9 has a diameter of 10 mm, smaller base 10 has a diameter of 7 mm and central blank hole 11 of smaller base 10 has a diameter of 4 mm. Furthermore, in the embodiment shown in the accompanying figures, pressing element 8 is compressed between lid 7 and printed circuit board 2 with a theoretical interference equal to 1.2 mm (more generally comprised between 1 mm and 1.5 mm).

According to a preferred embodiment, base 6 of housing 5 presents a contrast plane 15, which is arranged at pressing element 8 and constitutes a resting surface for printed circuit board 2 so as to act as a mechanical contrast for pressing element 8. In other words, without contrasting plane 15, printed circuit board 2 would centrally bend in undesired manner under the bias of pressing element 8.

According to a preferred embodiment, printed circuit board 2 is free from electric/electronic components 3 and weldings in the resting zone of pressing element 8 in order to prevent possible electric/electronic components 3 from being damaged in time by the pressure exerted by pressing element 8.

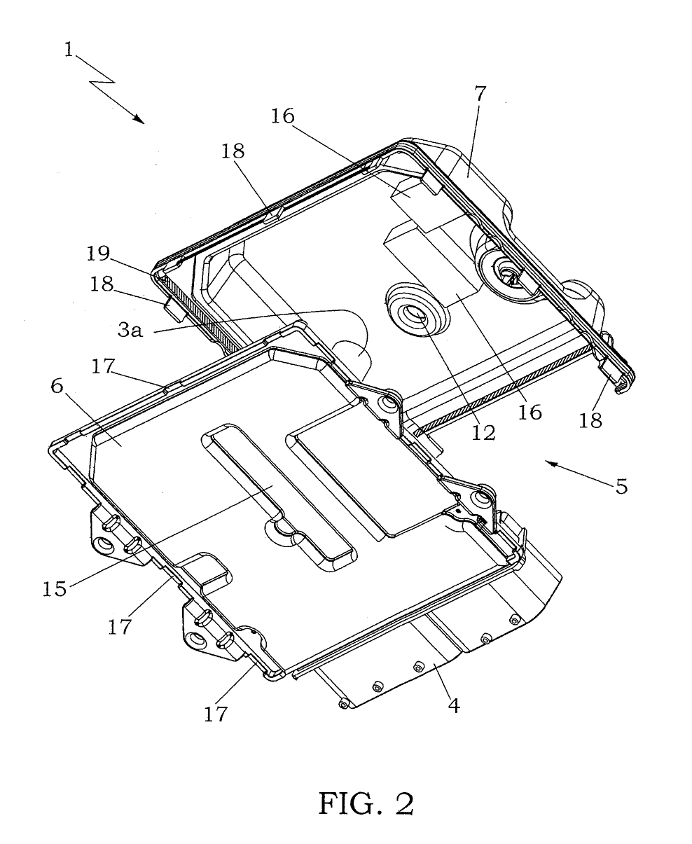

As shown in FIGS. 2 and 3, electronic control unit 1 comprises two blocking blocks 16 formed by deformable, expanded, elastic material, each of which is fixed (preferably glued) to an internal surface of lid 7 at two corresponding electrolytic capacitors 3a, presents a sufficient thickness so as to determine a vertical interference with the corresponding two electrolytic capacitors 3a to be compressed between lid 7 and electrolytic capacitors 3a, and presents a larger area with respect to electrolytic capacitors 3a to laterally encompass electrolytic capacitors 3a themselves.

In order words, each blocking block 16 by deforming superiorly and laterally encompasses corresponding electrolytic capacitors 3a contributing both to the axial withholding and to the lateral withholding of electronic capacitors 3a themselves. In virtue of the slight axial compression exerted by blocking blocks 16 on electrolytic capacitors 3a, electrolytic capacitors 3a themselves are essentially free from significant vibrations.

In the embodiment shown in the accompanying figures, each undeformed blocking block 16 presents a thickness of 10 mm and presents an interference of approximately 5 mm with electrolytic capacitors 3a.

According to a preferred embodiment, blocking blocks 16 are formed by open-cell expanded material because such material presents an optimal response to vibrations. For example, blocking blocks 16 may be formed by expanded polyurethane resin presenting a PPI equal to 20 and an ISO 845 density from 26 to 32 kg/m³.

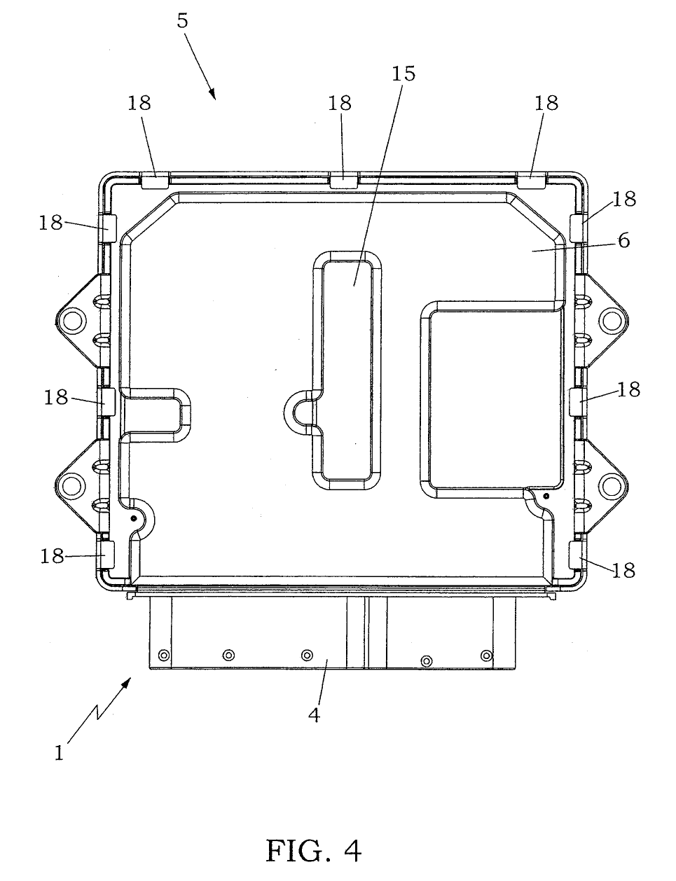

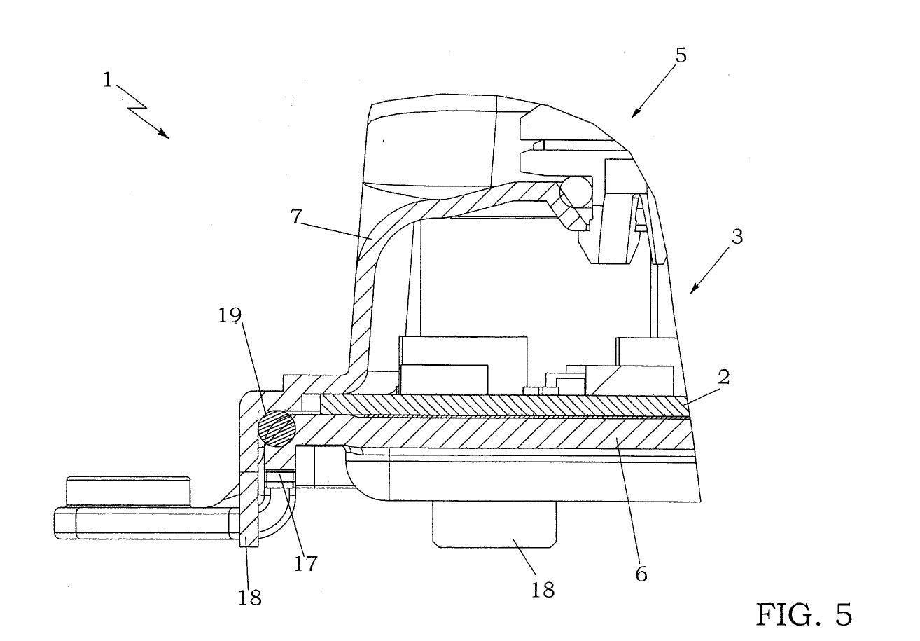

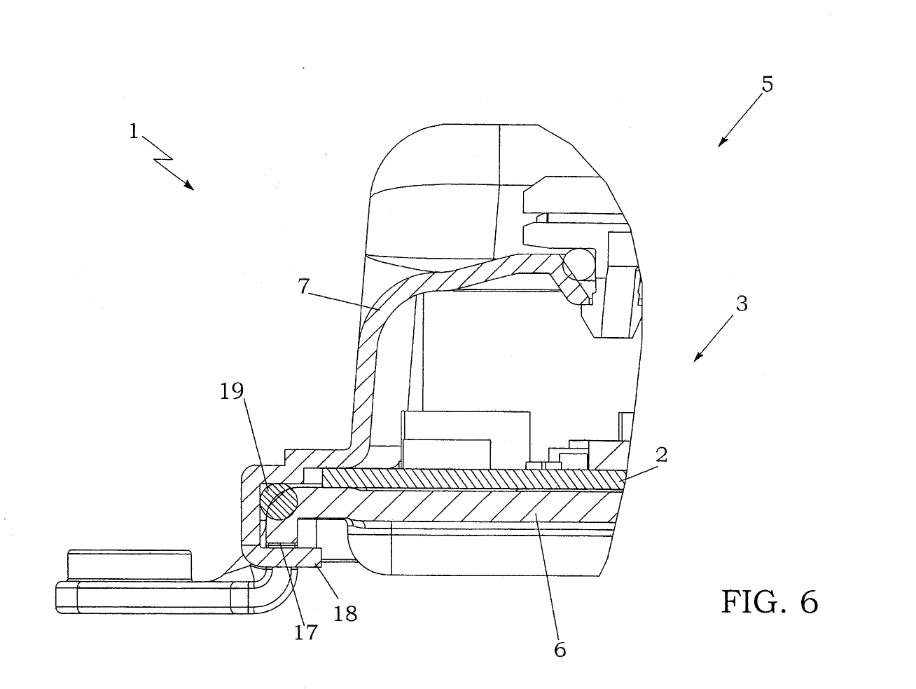

As shown in FIGS. 2-6, base 6 comprises a plurality of fastening seats 17 and lid 7 comprises a plurality of fastening fins 18, each of which is arranged at a corresponding fastening seat 17, is initially flat (FIG. 5), and is adapted to be plastically folded by at least 90° inside corresponding fastening seat 17 and against base 6 for fixing lid 7 to base 6 (FIG. 6).

In order words, lid 7 is fixed to base 6 by means of metallic fastening fins 17, which are integrally obtained in lid 7 (i.e. are monolithic with lid 7) and are plastically deformed (i.e. without subsequent elastic return) to encompass base 6; in this manner, it is possible to avoid the use of fastening screws.

According to a preferred embodiment, fastening fins 18 present a rectangular shape. Furthermore, in the embodiment shown in the accompanying figures, nine fastening fins 18 and nine fastening seats 17 symmetrically distributed in threes are contemplated on three sides of housing 5.

As shown in FIGS. 3, 5 and 6, a resin 19 having the function of adhesive seal, which adheres to the contact surfaces by polymerizing after housing 5 is closed, is interposed between lid 7 and base 6; resin 19 is dispensed with a circular section and then compressed by closing housing 5 and filling the empty spaces.

The above-described electronic control unit 1 presents a number of advantages, because it is simple and cost-effective to manufacture and does not require any central screw to maintain printed circuit board 2 pressed against base 6 of housing 5 because this function is performed by pressing element 8. Furthermore, by being elastic pressing element 8 also acts as a vibration damper and thus reduces the mechanical stresses induced by vibrations into printed circuit board 2.

1) An electronic control unit (1), comprising:
a printed circuit board (2), which supports an electric circuit, a plurality of electric/electronic components (3) electrically connected to the electric circuit, and at least one connector (4) electrically connected to the electrical circuit; and
a housing (5), which accommodates therein the printed circuit board (2) and comprises a base (6) which inferiorly supports the printed circuit board (2) and a lid (7) which superiorly closes the base (6);
the electronic control unit (1) is characterized in that it comprises at least one pressing element (8), which is formed by elastically deformable material, is arranged in central position and is compressed between the lid (7) and the printed circuit board (2) for pressing with interference against the printed circuit board (2).

2) An electronic control unit (1) according to claim 1, wherein the pressing element (8) presents a frustum shape having a larger first base (9) resting on the lid (7) and a smaller second base (10) resting on the printed circuit board (2).

3) An electronic control unit (1) according to claim 1, wherein a second base (10) of the pressing element (8) resting on the printed circuit board (2) presents a central blank hole (11).

4) An electronic control unit (1) according to claim 1, wherein a second base (10) of the pressing element (8) resting on the printed circuit board (2) is rounded.

5) An electronic control unit (1) according to claim 1, wherein a first base (9) of the pressing element (8) resting on the lid (7) is fixed to the lid (7) by means of gluing.

6) An electronic control unit (1) according to claim 1, wherein the lid (7) comprises a seat (12) which accommodates a first base (9) of the pressing element (8) resting on the lid (7).

7) An electronic control unit (1) according to claim 6, wherein the first base (9) of the pressing element (8) is fixed to the lid (7) by gluing.

8) An electronic control unit (1) according to claim 7, wherein at first base (9) the pressing element (8) presents at least one axial side channel (14) for relieving the glue in excess.

9) An electronic control unit (1) according to claim 6, wherein at first base (9) the pressing element (8) presents at least one annular bulge (13) dimensioned by interference within the seat (12).

10) An electronic control unit (1) according to claim 1, wherein the pressing element (8) is formed by silicone.

11) An electronic control unit (1) according to claim 10, wherein the silicone has a hardness equal to 80±5 shoreA.

12) An electronic control unit (1) according to claim 1, wherein the pressing element (8) has a total height of 27 mm and presents a frustum shape having a larger first base (9) resting on the lid (7) having a diameter of 10 mm and a smaller second base (10) resting on the printed circuit board (2) having a diameter of 7 mm.

13) An electronic control unit (1) according to claim 1, wherein the pressing element (8) is compressed between the lid (7) and the printed circuit board (2) with a theoretic interference from 1 mm to 1.5 mm.

14) An electronic control unit (1) according to claim 13, wherein the pressing element (8) is compressed between the lid (7) and the printed circuit board (2) with a theoretic interference equal to 1.2 mm.

15) An electronic control unit (1) according to claim 1, wherein the base (6) of the housing (5) presents a contrast plane (15), which is arranged at the pressing element (8) and constitutes a resting surface for the printed circuit board (2) so as to act as a mechanical contrast for the pressing element (8).

16) An electronic control unit (1) according to claim 1, wherein the printed circuit board (2) is free from electric/electronic components (3) and weldings in the resting zone of the pressing element (8).
